(19) United States
(12) Patent Application Publication
(10) Pub. No.: US 2007/0017565 A1
(43) Pub. Date: Jan. 25, 2007

(54) Liquid-metal cooled reactor equipped with alkali metal thermoelectric converter

(76) Inventors: Toshio Nakagiri, Higashi-Ibaraki-gun (JP); Kotaro Tanaka, Higashi-Ibaraki-gun (JP); Takeo Honda, Higashi-Ibaraki-gun (JP); Takahiro Fujii, Higashi-Ibaraki-gun (JP); Kazumi Aoto, Higashi-Ibaraki-gun (JP)

Correspondence Address: WENDEROTH, LIND & PONACK, L.L.P., 2033 K STREET N. W., SUITE 800, WASHINGTON, DC, 20006-1021, US

(21) Appl. No.: 11/377,427

(22) Filed: Mar. 17, 2006

(30) Foreign Application Priority Data
Jul. 25, 2005 (JP) 2005-214145

(51) Int. Cl. H01L 35/30

(52) U.S. Cl. 136/205

(57) ABSTRACT

In a liquid-metal cooled reactor equipped with a primary cooling system, a secondary cooling system and a steam turbine power generation system, or equipped with a primary cooling system and a steam power generation system, an alkali metal thermoelectric converter is disposed between the primary cooling system or the secondary cooling system and the steam turbine power generation system. Heat of the primary cooling system or the secondary cooling system is supplied to a high-temperature side of the alkali metal thermoelectric converter and waste heat on a low-temperature side of the alkali metal thermoelectric converter is supplied to the steam turbine power generation system. Thus, power generation by the steam turbine power generation system is performed simultaneously with power generation by the alkali metal thermoelectric converter. As a result, the power generation efficiency of the whole plant can be significantly increased.

### BACKGROUND OF THE INVENTION

The present invention relates to a new and improved liquid-metal cooled reactor which is improved in power generation efficiency by incorporating an alkali metal thermoelectric converter having a heat transport function in a liquid-metal cooled reactor.

An alkali metal thermoelectric converter is a type of concentration cell which performs power generation by giving a concentration difference (i.e., vapor pressure difference) of alkali metal vapor to both sides of a solid electrolyte, such as β″-alumina or the like, having alkali metal ion conductivity. Generators of various types of construction have hitherto been known and various proposals for improving these generators have also been made (for example, Japanese Patent Laid-Open No. 2005-39937, Japanese Patent Laid-Open No. 6-54566, Japanese Patent Laid-Open No. 6-163089, etc.).

The principle of an alkali metal thermoelectric converter will be described by taking an alkali metal thermoelectric converter of the vapor supply type shown in FIG. 4 as an example. The interior of a hermetically-sealed container 10 is constituted by a low-temperature side of a bottom portion and a high-temperature side of a top portion. Heat is supplied to the high-temperature side and heat is discharged from the low-temperature side. An alkali metal such as liquid sodium is stored in the bottom portion of the hermetically-sealed container on the low-temperature side, and this liquid sodium is sucked up by the capillary action of a wick (capillary tube for sodium circulation) 11 and becomes sodium vapor in an evaporation section on the high-temperature side. Sodium vapor heated to a high temperature dissociates into sodium ions (Na⁺) and electrons by an anode side porous electrode 12 of a power generation section. The sodium ions move and pass within a solid electrolyte 13 in the arrow direction by a driving force due to a vapor pressure difference of sodium vapor between the high-temperature side (high-pressure side: 10³ to 10⁵ Pa) and the low-temperature side (low-pressure side: 10⁻⁴ to 10² Pa). The electrons pass through an external load and are guided to a cathode side porous electrode 14. The electrons and the sodium ions bond together at an interface on the cathode side porous electrode 14 and power generation is performed.

The sodium ions which have bonded with the electrons become sodium vapor again, the sodium vapor is guided to the low-temperature side of the bottom portion within the hermetically-sealed container 10, returns to liquid sodium in the condensation section and is stored in the bottom portion within the hermetically-sealed container 10. This liquid sodium is again circulated by the wick 11 to the high-temperature side evaporation section of the top portion within the hermetically-sealed container 10, whereby power generation is continued.

Incidentally, although it is possible to use an electromagnetic pump in place of the wick for liquid sodium circulation, in the case where the wick which utilizes the capillary action is used, external power is unnecessary and hence a simple equipment constitution becomes possible.

Examinations of the adoption of such an alkali metal thermoelectric converter as a power generation system of a liquid-metal cooled reactor have been widely carried out at home and abroad. However, the power generation efficiency of an alkali metal thermoelectric converter which operates at about 500° C. to 700° C. or so, which are coolant temperatures of a liquid-metal cooled reactor, is not more than about 20%, and an alkali metal thermoelectric converter could not become a power generation system comparable with the power generation efficiency of a steam turbine power generation system (about 40% in a sodium-cooled fast reactor with a coolant temperature of about 500° C.).

Also, in the case of a power generation system using a steam turbine, it was difficult to ensure that the power generation efficiency significantly exceeds about 40% when the temperature of supplied heat is about 500° C.

### SUMMARY OF THE INVENTION

Therefore, an object of the present invention is to provide a liquid-metal cooled reactor equipped with an alkali metal thermoelectric converter in which the alkali metal thermoelectric converter is incorporated in a liquid-metal cooled reactor so that the power generation efficiency of the whole plant can be significantly increased in comparison with the power generation efficiency of a singly used conventional steam turbine power generation system which has hitherto been adopted in a liquid-metal cooled reactor.

According to the present invention, there is provided a liquid-metal cooled reactor equipped with an alkali metal thermoelectric converter, characterized in that the liquid-metal cooled reactor is equipped with a primary cooling system, a secondary cooling system and a steam turbine power generation system, or the liquid-metal cooled reactor is equipped with a primary cooling system and a steam power generation system; that the alkali metal thermoelectric converter is disposed between the primary cooling system or the secondary cooling system and the steam turbine power generation system; and that heat of the primary cooling system or the secondary cooling system is supplied to a high-temperature side of the alkali metal thermoelectric converter and waste heat on a low-temperature side of the alkali metal thermoelectric converter is supplied to the steam turbine power generation system, whereby power generation by the steam turbine power generation system is performed simultaneously with power generation by the alkali metal thermoelectric converter.

It is preferred that a vapor supply type alkali metal thermoelectric converter having a high heat transport capacity be used as the alkali metal thermoelectric converter.

In a preferred embodiment of the present invention, the alkali metal thermoelectric converter is an alkali metal thermoelectric conversion cell comprising a hermetically-sealed cylindrical container; a low-temperature condensation section at a heat discharge side provided on a bottom surface within the hermetically-sealed cylindrical container; a plurality of high-temperature cylindrical power generation elements each having an inner cavity, the power generation elements being arranged in a standing manner so as to be juxtaposed on an upper heat absorption side within the hermetically-sealed cylindrical container; and a plurality of wicks juxtaposed so that one end of each of the wicks is positioned in the condensation section and the other end thereof is positioned in the inner cavity of each of the cylindrical power generation elements.

When such an alkali metal thermoelectric conversion cell is used, it is preferred that the plurality of cylindrical power generation elements of the alkali metal thermoelectric conversion cell are densely juxtaposed.

In the present invention, power generation by the alkali metal thermoelectric converter is performed by using heat of the primary or secondary cooling system of the liquid-metal cooled reactor and, in addition, power generation by the steam turbine power generation system is performed by supplying waste heat on the low-temperature side of the alkali metal thermoelectric converter to the steam turbine power generation system by utilizing the heat transport function of the alkali metal thermoelectric converter. Thus, power generation by both the alkali metal thermoelectric converter and the steam turbine power generation system becomes possible by utilizing the alkali metal thermoelectric converter having the heat transport function as heat exchange means between the primary or secondary cooling system and the steam turbine power generation system. Even when the power generation efficiency of alkali metal thermoelectric conversion is low, the overall power generation efficiency of the whole plant in combination with the steam turbine power generation system can be significantly increased as compared to a case where the steam turbine power generation system is singly used.

When the alkali metal thermoelectric converter is installed within a reactor container, there is an important problem that the installation area of the equipment within the container must not be increased. Because the alkali metal thermoelectric converter used in the present invention can perform power generation simultaneously with heat transport with the same size as conventional heat transport equipment, installation of this alkali metal thermoelectric converter does not increase the installation area within the container.

Particularly, when a vapor supply type alkali metal thermoelectric converter which utilizes the evaporation and condensation of an alkali metal is used, a large heat transport volume can be obtained by utilizing the heat pipe function and a high heat transport volume per heat-receiving area becomes possible, with the result that the heat transfer area necessary for heat exchange can be decreased as compared to a conventional type heat exchanger.

Further, in a case where, as the alkali metal thermoelectric converter, there is used an alkali metal thermoelectric conversion cell having a construction that a plurality of cylindrical power generation elements are arranged in a standing manner so as to be juxtaposed within the hermetically-sealed cylindrical container, replacement work becomes easy in the case of a failure of the cell and it becomes possible to improve maintainability. Furthermore, by densely juxtaposing cylindrical power generation elements, economies of scale can also be expected and an inexpensive power generation system can be provided.

### BRIEF DESCRIPTION OF THE DRAWINGS

FIG. 1 is a perspective view which shows an embodiment of an alkali metal thermoelectric conversion cell capable of being used in the present invention.

FIG. 2 is a graph which shows the relationship among the current density (heat transport capacity), output and power generation efficiency in the alkali metal thermoelectric conversion cell of FIG. 1.

FIG. 3 is an explanatory diagram which shows an embodiment of the present invention.

FIG. 4 is an explanatory diagram which shows the principle of an alkali metal thermoelectric converter used in the present invention.

### PREFERRED EMBODIMENTS OF THE INVENTION

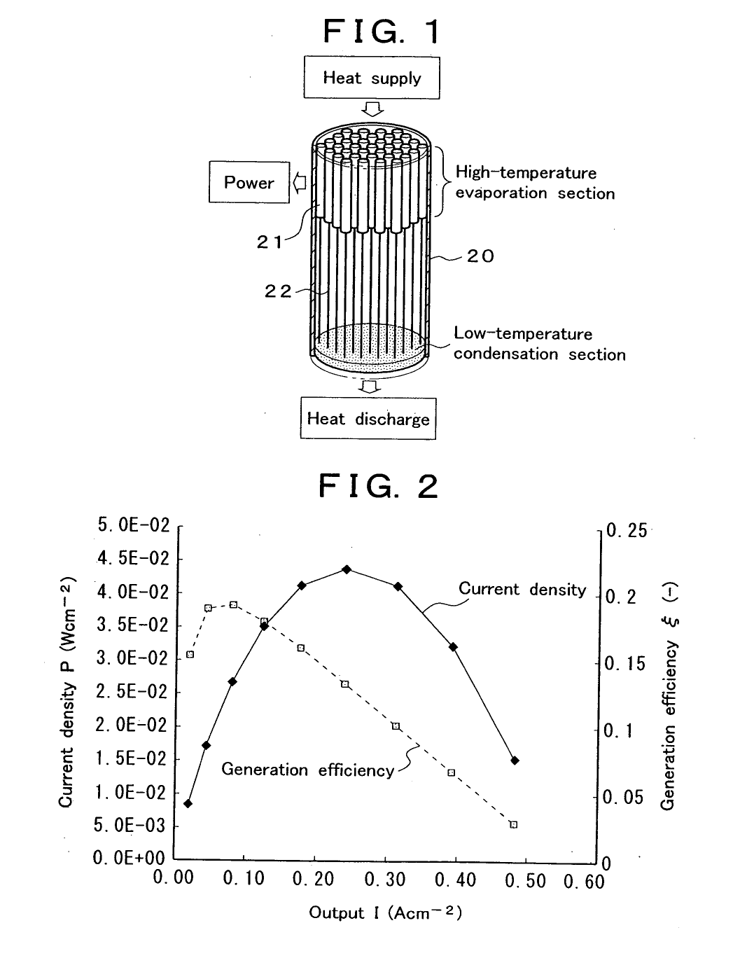

An alkali metal thermoelectric converter which can be used in the present invention is not especially limited so long as it is an alkali metal thermoelectric converter having the heat transport function. An alkali metal thermoelectric converter having a basic construction as shown in FIG. 4 and an alkali metal thermoelectric conversion cell of a compact construction as shown in FIG. 1 can be advantageously used.

The cell structure of FIG. 1 will be described. In the interior of a hermetically-sealed cylindrical container 20 (for example, made of stainless steel, inside diameter: 30 mm, length: 75 mm), a high-temperature evaporation section which receives heat supply (for example, 500° C., which is the temperature of a liquid sodium coolant) is formed in an upper portion and a low-temperature condensation section which discharges heat (for example, 250° C.) is formed on a bottom surface. In the high-temperature evaporation section, a plurality of cylindrical power generation elements 21 each having an inner cavity and made of β″-alumina are arranged in a standing manner so as to be juxtaposed. Electrodes made of TiN, Mo, etc. are attached to inner and outer surfaces of the β″-alumina which forms the power generation element 21. Furthermore, a plurality of wicks 22 are disposed so that one end of each of the wicks is positioned in the condensation section and the other end thereof is positioned in the inner cavity of each of the power generation elements 21.

The power generation operation of such a cell structure is as follows. Liquid sodium which is stored in the condensation section on the bottom surface is sucked up by the capillary action of the wick 22 which utilizes surface tension and is evaporated in the inner cavity of the high-temperature cylindrical power generation element 21 to become sodium vapor (sodium ions). The sodium vapor is discharged outside the power generation element 21, with a vapor pressure difference inside and outside the power generation element 21 serving as a driving force, and moves to the condensation section on the bottom surface having a low temperature and a low sodium vapor pressure, where the sodium vapor condenses and becomes liquid sodium. Power is generated when sodium ions pass through the interior of the power generation element 21 made of β″-alumina, and power generation is performed.

In the example of FIG. 1, within a hermetically-sealed cylindrical container 20 having an inside diameter of 30 mm, 37 power generation elements 21 having a diameter of 5 mm are densely juxtaposed. As a result of this, the proportion of the sectional area of the 37 power generation elements 21 with respect to the sectional area of the cylindrical container 20 can be made 37% and it is possible to obtain a compact alkali metal thermoelectric conversion cell with high economies of scale.

The relationship among the current density (heat transport capacity), output and power generation efficiency in the sodium thermoelectric conversion cell having the construction of FIG. 1 is shown in the graph of FIG. 2.

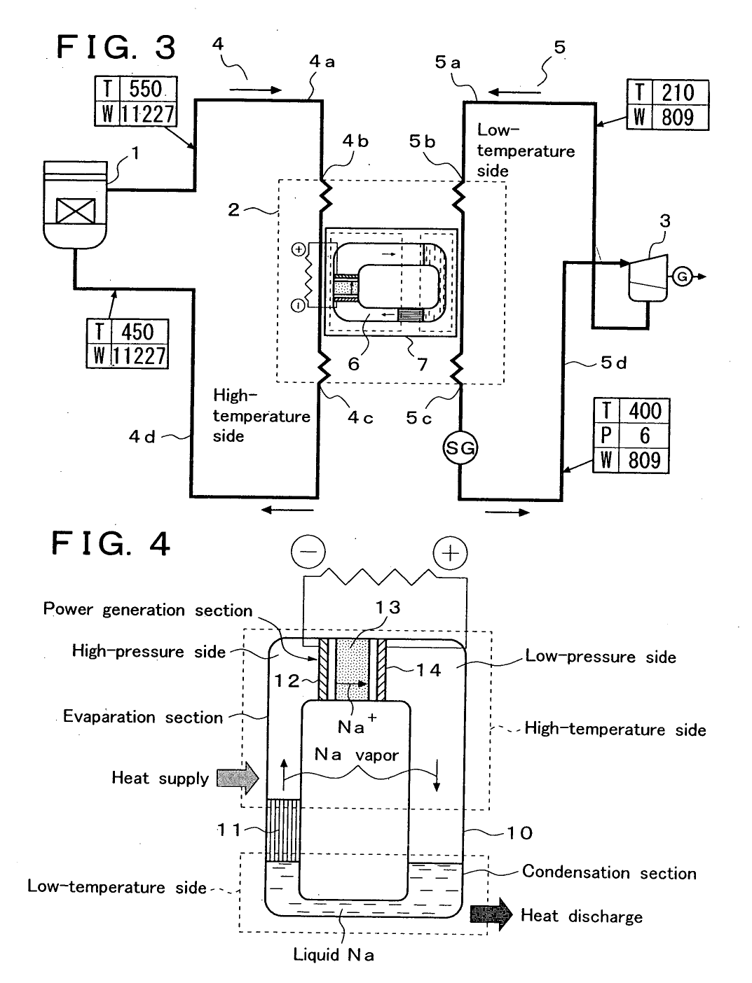

FIG. 3 shows an embodiment of the present invention in which an alkali metal thermoelectric converter (AMTEC) is disposed between a primary sodium cooling system and a steam turbine power generation system of a liquid-metal cooled reactor.

In the example of FIG. 3, the basic construction is such that a primary sodium cooling system 4 of a reactor 1 is connected to a high-temperature side of an AMTEC 2 and a steam system 5 of a steam turbine generator 3 is connected to a low-temperature side of the AMTEC 2. The AMTEC 2 has the same construction as shown in FIG. 4. A sodium coolant which has reached a high temperature after cooling the reactor 1 is guided to a high-temperature side inlet 4b of the AMTEC 2 via a high-temperature side pipe 4a of the primary sodium cooling system 4, which is connected to a coolant outlet of the reactor, heat exchange is performed within the AMTEC 2, and after that, the sodium coolant is returned from a high-temperature outlet 4c of the AMTEC 2 to the reactor 1 via a high-temperature side pipe 4d, which is connected to a coolant inlet of the reactor.

On the other hand, steam the temperature of which has been lowered by the steam turbine generator 3 is guided to a low-temperature side inlet 5b of the AMTEC 2 via a low-temperature side pipe 5a of the steam system 5, which is connected to a steam outlet of the steam turbine generator 3, heat exchange is performed within the AMTEC 2, and after that, the steam is guided from a low-temperature side outlet 5c of the AMTEC 2 to a steam generator SG, where the steam became high-temperature steam. This high-temperature steam is introduced into the steam turbine generator 3 from a low-temperature side pipe 5d, which is connected to a steam inlet of the steam turbine generator 3, and used in power generation. Incidentally, in the illustrated example, the steam generator SG is installed downstream of the low-temperature side outlet 5c of the AMTEC2. However, it is also possible to install the steam generator SG within the AMTEC 2 between the low-temperature side inlet 5b and the low-temperature side outlet 5c.

In this process, within the AMTEC 2, due to a temperature difference between the high-temperature sodium coolant of the primary sodium cooling system 4 and the low-temperature steam of the steam system 5, the alkali metal thermoelectric converter performs its function on the basis of the above-described principle for electric generation.

Within the AMTEC 2, a sodium circulation system 6 different from the primary sodium cooling system 4 and the steam system 5 is formed, and this sodium circulation system 6 has the function of a secondary sodium cooling system. The sodium circulation system 6 is formed within a hermetically-sealed container 7 made of stainless steel or the like, and piping of the primary sodium cooling system 4 and piping of the steam system 5 are each disposed in contact with an outer wall of the hermetically-sealed container 7. Therefore, heat exchange between each piping and the hermetically-sealed container is carried out via outer walls of each piping and the outer wall of the hermetically-sealed container 7. As a result of this, the sodium of the primary sodium cooling system 4 and the sodium circulation system 6 does not come into contact with the water of the steam system 5 and it is possible to eliminate the occurrence of a sodium-water reaction. Within the sodium circulation system 6, the sodium evaporates due to heat exchange with the primary sodium cooling system 4 on the high-temperature side, and generated sodium vapor moves to the low-temperature side and condenses by heat exchange with the steam system 5. Within the AMTEC 2, heat transport between the high-temperature side and the low-temperature side is carried out due to this evaporation-condensation cycle, with the result that the AMTEC 2 performs the function of an intermediate heat exchanger.

The symbols T (temperature, ° C.) and W (flow rate, ton/h) in the primary sodium cooling system 4 shown in FIG. 3 indicate numerical values determined from reactor design, and the symbols T (temperature, ° C.), W (flow rate, ton/h) and P (pressure, MPa) in the steam system 5 indicate numerical values determined from heat balance in which heat quantities consumed in the primary sodium cooling system 4 and the AMTEC 2 are considered. As the reactor 1, a small-size fast reactor having a heat output of 395 MWt, which is being examined by Japan Atomic Energy Agency, is taken into consideration, and generated electricity in the AMTEC 2 can be calculated as follows.
395 MWt×17.8% (power generation efficiency of AMTEC) =70.3 MWe
where the power generation efficiency of AMTEC of 17.8% was calculated according to a dedicated evaluation program by using the specifications for the power generation cell and temperature conditions (high-temperature side and low-temperature side) of AMTEC.

The generated electricity (G) of the steam turbine generator 3 can be calculated as follows.
Quantity of heat supplied to generator (395 MWt−70.3MWe)×38% (power generation efficiency of generator)=123.4 MWe

The power generation efficiency and generated electricity of the AMTEC 2 and turbine generator 3, and the total generated electricity and total power generation efficiency of the whole system, which were obtained above, are as follows:

Power generation efficiency and generated electricity of the AMTEC: 17.8% and 70.3 MWe, respectively.

Power generation efficiency and generated electricity of the turbine generator: 38% and 123.4 MWe, respectively.

Total generated electricity and total power generation efficiency of the whole system: 193.7 MWe and 49.0%, respectively.

From the above-described numerical values, it is apparent that in the above-described embodiment as shown in FIG. 3, even when the power generation efficiency of the AMTEC 2 is low, the power generation efficiency of the whole system in combination with the steam turbine generator 3 can be improved by about 9% as compared to the power generation efficiency when the steam turbine generator is singly used (about 40% in a small-size sodium-cooled fast reactor with a coolant temperature of about 500° C.).

What is claimed:

1. A liquid-metal cooled reactor equipped with an alkali metal thermoelectric converter, characterized in that the liquid-metal cooled reactor is equipped with a primary cooling system, a secondary cooling system and a steam turbine power generation system, or the liquid-metal cooled reactor is equipped with a primary cooling system and a steam power generation system; that the alkali metal thermoelectric converter is disposed between the primary cooling system or the secondary cooling system and the steam turbine power generation system; and that heat of the primary cooling system or the secondary cooling system is supplied to a high-temperature side of the alkali metal thermoelectric converter and waste heat on a low-temperature side of the alkali metal thermoelectric converter is supplied to the steam turbine power generation system, whereby power generation by the steam turbine power generation system is performed simultaneously with power generation by the alkali metal thermoelectric converter.

2. The liquid-metal cooled reactor equipped with an alkali metal thermoelectric converter according to claim 1, characterized in that the alkali metal thermoelectric converter is a vapor supply type alkali metal thermoelectric converter having a high heat transport capacity.

3. The liquid-metal cooled reactor equipped with an alkali metal thermoelectric converter according to claim 2, characterized in that the alkali metal thermoelectric converter is an alkali metal thermoelectric conversion cell comprising a hermetically-sealed cylindrical container; a low-temperature condensation section at a heat discharge side provided on a bottom surface within the hermetically-sealed cylindrical container; a plurality of high-temperature cylindrical power generation elements each having an inner cavity, the power generation elements being arranged in a standing manner so as to be juxtaposed on an upper heat absorption side within the hermetically-sealed cylindrical container; and a plurality of wicks juxtaposed so that one end of each of the wicks is positioned in the condensation section and the other end thereof is positioned in the inner cavity of each of the cylindrical power generation elements.

4. The liquid-metal cooled reactor equipped with an alkali metal thermoelectric converter according to claim 3, characterized in that the plurality of cylindrical power generation elements of the alkali metal thermoelectric conversion cell are densely juxtaposed.
